(19) United States
(12) Patent Application Publication
(10) Pub. No.: US 2004/0262619 A1
(43) Pub. Date: Dec. 30, 2004

(54) Semiconductor device having light-receiving elements and amplifying elements incorporated in the same chip and method of manufacturing the same

(75) Inventors: Kenichiro Takahashi, Seoul (KR); Kyeong-Ik Min, Kyunggi-Do (KR); Jea-Shik Shin, Kyunggi-Do (KR)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Samsung Electro-Mechanics Co., Ltd.

(21) Appl. No.: 10/742,159

(22) Filed: Dec. 18, 2003

(30) Foreign Application Priority Data
Jun. 27, 2003 (KR) 2003-42638

(51) Int. Cl. H01L 27/15

(52) U.S. Cl. 257/79

(57) ABSTRACT

Disclosed herein are a semiconductor device having light-receiving elements and amplifying elements incorporated in the same chip and a method of manufacturing the same. The semiconductor device comprises a plurality of light-receiving elements for receiving optical signals having predetermined wavelengths reflected from an optical recording medium to convert the received optical signals into electric signals, and amplifying elements for amplifying the electric signals outputted from the light-receiving elements to externally transmit the amplified electric signals. The light-receiving elements are arranged in a lattice pattern. The amplifying elements are spaced apart from each other by a predetermined distance in a lattice pattern while being interposed between the light-receiving elements.

### BACKGROUND OF THE INVENTION

1. Field of the Invention

The present invention relates to a semiconductor device having light-receiving elements and amplifying elements incorporated in the same chip, which is used in optical pick-up devices, and to a method of manufacturing the same.

More particularly, the present invention relates to a semiconductor device comprising light-receiving elements for receiving light reflected from an optical disc to convert the received light into electric signals, and amplifying elements for amplifying the electric signals outputted from the light-receiving elements wherein the light-receiving elements and the amplifying elements are incorporated in the same chip, whereby the S/N ratio of the semiconductor device is improved.

2. Description of the Related Art

In an optical pick-up device for projecting light from a laser diode onto an optical disc, such as a compact disc (hereinafter referred to as CD) or a digital versatile disc (hereinafter referred to as DVD), to read out information recorded on the optical disc, a photodiode is widely used as a light-receiving element for detecting light reflected from the optical disc to convert the detected light into an electric signal.

The photodiode applied to the optical pick-up device for reading out information recorded on the CD or the DVD is generally a PIN photodiode realized in the form of a vertical type semiconductor chip, which is generally used.

The signal detected by the aforesaid photodiode is very low, and thus the signal is attenuated while it is applied to another external device. To compensate for the attenuation of the signal, an amplifying element for amplifying the output signal from the photodiode is realized in the form of a chip, and the amplifying element is connected to the photodiode by means of a lead frame or a bonding wire on a package, which is disclosed.

On the other hand, it is required that another photodiode other than the aforesaid photodiode applied to the optical pick-up device for reading out information recorded on the CD or the DVD be used as a photodiode applied to an optical pick-up device for reading out information recorded on a so-called “Blu-ray” disc.

On the Blu-ray disc, a laser beam having a relatively short wavelength is used, unlike the CD or the DVD. Consequently, the sensitivity of the photodiode is as low as 327 mA/W even though quantum efficiency is 100 percent, i.e., all of carriers generated under the condition that every photon creates electron-hole pairs (e-h pairs) are contributed as output current. This sensitivity is very poor as compared to the sensitivity of the CD having a wavelength of 780 nm, which is 629 mA/W, and the sensitivity of the DVD having a wavelength of 650 nm, which is 525 mA/W.

Also, the depth of light permeating into silicon of a semiconductor substrate is 9 μm for the CD and 5 μm for the DVD while the depth of light permeating into silicon of a semiconductor substrate is 0.4 μm for the Blu-ray disc. That is to say, the depth of light permeating into silicon of a semiconductor substrate for the Blu-ray disc is smaller than the depth of light permeating into silicon of a semiconductor substrate for the CD or the DVD. As a result, the ratio of generation of carriers near the surface where the rejoining speed is high becomes higher, whereas the quantum efficiency becomes lower.

Consequently, the sensitivity of the photodiode applied to the Blu-ray disc is low to the extent that it is no match for the sensitivity of the photodiode applied to the CD or the DVD with the result that a good S/N ratio is not obtainable, a good error rate is not also obtainable from a regenerative signal, and thus high-speed playback is not possible.

Recently, development of photodiodes applicable to the Blu-ray disc has been initiated, one example of which is disclosed in a paper entitled “ADVANCED PHOTODIODES FOR OPTO-ASICS” published in PROCEEDINGS EDMO2001/VIENNA, wherein a finger photodiode having a depletion layer reaching the surface of a semiconductor substrate is suggested.

However, the S/N ratio of the above-mentioned finger photodiode is considerably low as compared to that of the photodiode for the CD or the DVD. Consequently, the finger photodiode will hinder prospective high-speed playback of the Blu-ray disc.

As the photodiode for the CD or the DVD is commonly used a vertical type PIN photodiode, which is disclosed in U.S. Pat. No. 4,831,430 and U.S. Pat. No. 5,770,872. On the other hand, transmissivity of a laser beam into silicon is very low for the Blu-ray disc, which requires the depletion layer to be arranged to the surface of the semiconductor substrate. In order to realize the structure mentioned above, a lateral type photodiode, for which the aforesaid finger photodiode stands, is applied.

Now, the construction of a semiconductor device for a vertical type photodiode applicable to the CD or the DVD will be described in detail with reference to FIG. 1.

FIG. 1 is a sectional view showing a conventional semiconductor device for the vertical type photodiode. The photodiode, which is generally a light-receiving element, is manufactured using a process for manufacturing a bipolar transistor.

In the semiconductor for photodiodes shown in FIG. 1, a substrate 60 is formed from a P+ type silicon semiconductor. On the substrate 60 is formed a P type epitaxial silicon layer 62 having a thickness of approximately 20 μm.

The epitaxial silicon layer 62 comprises a first layer part 64 formed on the substrate 60 and a second layer 66 formed on the first layer 64. The first layer 64 is an autodoped layer obtained by epitaxially growing a silicon semiconductor layer on the substrate 60 so that the impurity in the substrate 60 is diffused in the upper growing epitaxial layer.

The first layer 64 has a thickness of, for example, approximately 15 μm. The impurity concentration of the first layer 64 decreases as it moves closer to the second layer 66. The second layer 66 is a P− type epitaxial layer in which an impurity is lightly doped.

On the P type epitaxial silicon layer 62 is formed an N type epitaxial silicon layer 68 having a thickness of approximately 5 μm. A silicon oxide insulation layer 70 is formed on the N type epitaxial silicon layer 68.

The N type epitaxial silicon layer 68 is divided into a plurality of N type epitaxial silicon regions 68a and 68b by P+ type isolation diffusion regions 72 which connect the second layer 66 and the silicon oxide insulation layer 70 and are arranged with an appropriate space therebetween.

The N type epitaxial silicon region 68a is constituted as a photodiode element. In the photodiode element region, a P-N junction is formed between the N type epitaxial silicon region 68a and the P− type epitaxial layer 66, which in turn forms an active region as the photodiode element. A N+ type contact region 74 is formed on a surface of the N type epitaxial silicon region 68a on the side of the silicon oxide insulation layer 70. The N+ type contact region 74 is formed for connection with an electrode. A portion of the silicon oxide insulation layer 70 is removed to coincide with the N+ type contact region 74.

An aluminum electrode 76 is in the empty portion. The aluminum electrode 76 makes ohmic contact with the N+ type contact region 74. Each of the P+ type isolation diffusion regions 72 serves as an electrode connecting region for the layer 66 constituting a part of the photodiode element.

Peripheral circuit elements, such as a transistor and a resistor, are formed on the other N type epitaxial silicon region 68b. As shown in FIG. 1, an NPN transistor is formed in the N type epitaxial silicon region 68b. A N+ type buried region 78 is formed in the peripheral circuit region in the interface between the epitaxial silicon layer 62 and the N type epitaxial silicon layer 68 (specifically, the N type epitaxial silicon region 68b).

The N+ type buried region 78 acts to decrease the collector resistance. A P type base region 80 is formed in the N type epitaxial silicon region 68b near the silicon oxide insulation layer 70. A N+ type emitter region 82 is formed in the P type base region 80 near the silicon oxide insulation layer 70. A portion of the silicon oxide insulation layer 70 is removed to coincide with the N+ type emitter region 82 and the P type base region 80. Aluminum electrodes are formed in the empty portions where the silicon oxide insulation layer 70 is removed. An electrode 88, which makes ohmic contact with the P+ type isolation diffusion region 72, and an electrode 86, which also makes ohmic contact with the P type base region 80, are connected to each other by means of wiring 84. An electrode 90 makes ohmic contact with the N+ type emitter region 82.

FIG. 2 is a plan view showing a package wherein the optical semiconductor device with the above-stated construction is assembled.

The semiconductor chip 92 having the structure mentioned above is assembled in a package 94, and connected to lead frames 96 by means of bonding wires 98. The semiconductor chip 92 may be connected to another semiconductor chip having other circuit elements, for example, amplifying elements by means of the lead frames 96.

In the package as described above, the signal from the photodiodes, which are the light-receiving elements, is generally amplified by the semiconductor chip having the amplifying elements, which is connected to the package by means of the bonding wire or the lead frames.

When an initial amplifying operation is performed closest to the place where photons create electron-hole pairs (e-h pairs), however, noise is overlapped because of wiring, which is carried out later.

Consequently, noise is generated depending upon a high-frequency resistance component due to the bonding wires or the lead frames connecting the light-receiving elements and the amplifying elements with the result that the S/N ratio is very poor, and thus a high-speed playback is not possible. Especially, the negative effect is more serious for the Blu-ray disc.

### SUMMARY OF THE INVENTION

Therefore, the present invention has been made in view of the above problems, and it is an object of the present invention to provide a semiconductor device having light-receiving elements for receiving light reflected from an optical disc, such as a Blu-ray disc, to convert the received light into electric signals and amplifying elements for amplifying the electric signals outputted from the light-receiving elements wherein the light-receiving elements and the amplifying elements are incorporated in the same chip, whereby the S/N ratio is improved, and a method of manufacturing the same.

In accordance with the present invention, the above and other objects can be accomplished by the provision of a semiconductor device comprising: a plurality of light-receiving elements for receiving optical signals having predetermined wavelengths reflected from an optical recording medium to convert the received optical signals into electric signals, the light-receiving elements being arranged in a lattice pattern; and amplifying elements for amplifying the electric signals outputted from the light-receiving elements to externally transmit the amplified electric signals, the amplifying elements being spaced apart from each other by a predetermined distance in a lattice pattern while being interposed between the light-receiving elements.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view showing a conventional semiconductor device for vertical type photodiodes;

FIG. 2 is a plan view showing a package wherein the semiconductor device for vertical type photodiodes is assembled;

FIGS. 3 and 4 are plan views respectively showing a semiconductor device having light-receiving elements and amplifying elements incorporated in the same chip according to the present invention wherein each of the light-receiving elements has an N sink region formed therein;

FIGS. 5 and 6 are plan views respectively showing a semiconductor device having light-receiving elements and amplifying elements incorporated in the same chip according to the present invention wherein each of the light-receiving elements has no N sink region formed therein;

FIG. 7 is a sectional view showing a semiconductor device having light-receiving elements and amplifying elements incorporated in the same chip according to a first preferred embodiment of the present invention;

FIGS. 8a to 8c are sectional views showing successive steps of a process for manufacturing a semiconductor device having light-receiving elements and amplifying elements incorporated in the same chip according to a first preferred embodiment of the present invention;

FIG. 9 is a sectional view showing a semiconductor device having light-receiving elements and amplifying elements incorporated in the same chip according to a second preferred embodiment of the present invention;

FIGS. 10a to 10d are sectional views showing successive steps of a process for manufacturing a semiconductor device having light-receiving elements and amplifying elements incorporated in the same chip according to a second preferred embodiment of the present invention;

FIG. 11 is a sectional view showing a semiconductor device having light-receiving elements and amplifying elements incorporated in the same chip according to a third preferred embodiment of the present invention; and

FIGS. 12a to 12f are sectional views showing successive steps of a process for manufacturing a semiconductor device having light-receiving elements and amplifying elements incorporated in the same chip according to a third preferred embodiment of the present invention.

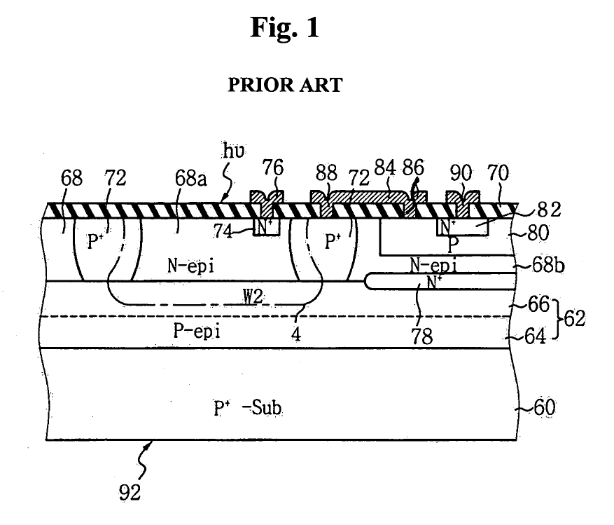

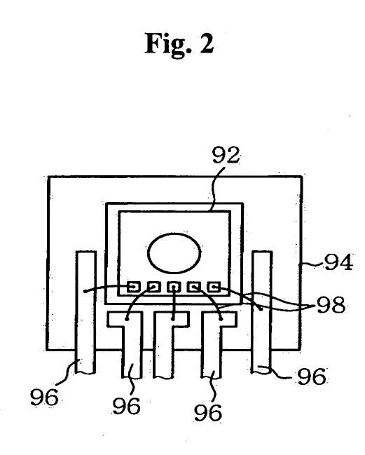

### DESCRIPTION OF THE PREFERRED EMBODIMENTS

Now, a semiconductor device having light-receiving elements and amplifying elements incorporated in the same chip according to the present invention and a method of manufacturing the same will be described in detail with reference to the accompanying drawings.

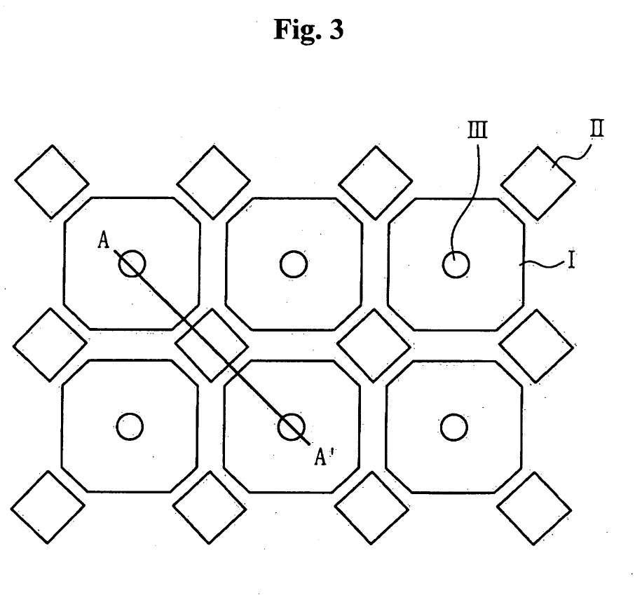

Firstly, the construction of the semiconductor device having light-receiving elements and amplifying elements incorporated in the same chip according to the present invention will be described in detail with reference to FIGS. 3 to 6.

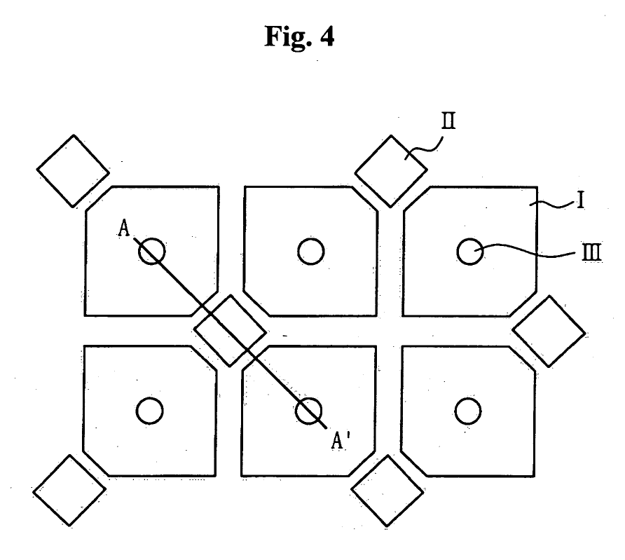

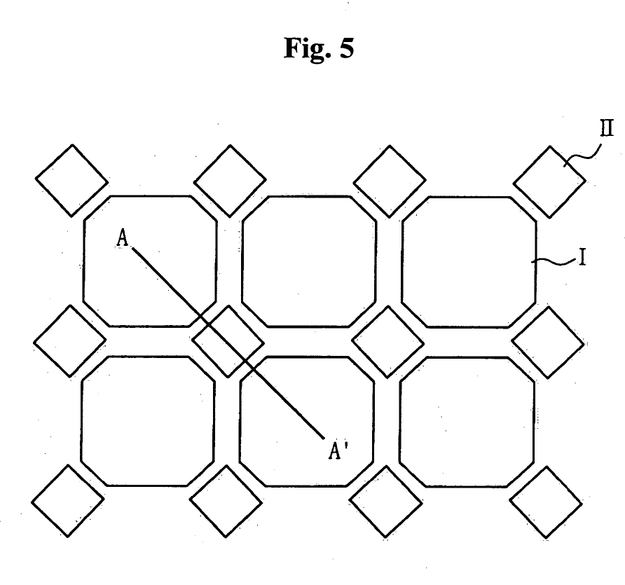

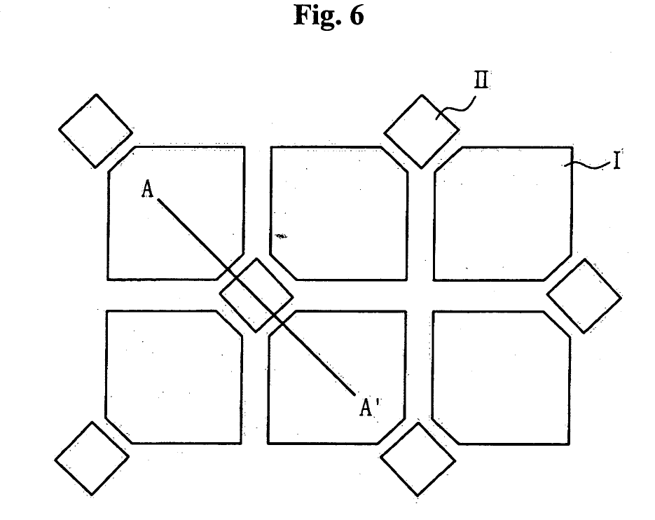

FIGS. 3 and 4 are plan views respectively showing the semiconductor device having light-receiving elements and amplifying elements incorporated in the same chip according to the present invention wherein each of the light-receiving elements has an N sink region formed therein, and FIGS. 5 and 6 are plan views respectively showing the semiconductor device having light-receiving elements and amplifying elements incorporated in the same-chip according to the present invention wherein each of the light-receiving elements has no N sink region formed therein.

Referring to FIGS. 3 to 6, there is shown a light-receiving unit used in a three-beam type optical pick-up device. The light-receiving unit comprises a plurality of light-receiving elements, which are constituted by photodiodes, i.e., four partitioned focusing parts for performing a focusing operation on inputted optical signals and two tracking parts formed at both sides of the focusing parts for performing a tracking operation on inputted optical signals. FIGS. 3 to 6 clearly show regions where the plurality of photodiodes constituting four partitioned focusing parts and two tracking parts of the light-receiving unit are formed, and regions where the transistors interposed between the photodiodes in a lattice pattern are formed.

As shown in FIG. 3, four bipolar transistor formation regions II are disposed around the each of the photodiode formation regions I.

In the semiconductor device having light-receiving elements and amplifying elements incorporated in the same chip according to the present invention, the plurality of photodiode formation regions I are arranged in a lattice pattern while the photodiode formation regions I are spaced apart from each other by a predetermined distance, and the bipolar transistor formation regions II are interposed between the photodiode formation regions I while the bipolar transistor formation regions II are spaced apart from each other by a predetermined distance, for example, in such a manner that the bipolar transistor formation regions II surround the photodiode formation regions I at the four corners or at the two corners, as shown in FIGS. 3 and 4.

The arrangement of the bipolar transistor formation regions II shown in FIG. 3 is different from that of FIG. 4 in that the distance between the bipolar transistor formation regions II surrounding the photodiode formation regions I is different. Specifically, two bipolar transistor formation regions are provided for one photodiode formation region I, as shown in FIG. 4.

The reason why the distance between the bipolar transistor formation regions II surrounding the photodiode formation regions I is differently set is that there exists an optimum value even for an ultra-short bipolar transistor having a size equivalent to an area of the emitter. Consequently, a sufficient amplification rate is not obtainable when the area of the emitter is small and an implanting process is carried out with relatively weak current.

On the other hand, a capacity between the emitter and the base is increased as an area of the emitter increases. Consequently, it takes times to charge up over an emitter-base barrier, the frequency characteristics are deteriorated, and thus the ratio of carriers rejoining between the emitter and the base, which decreases the amplification rate.

In order to solve the above-mentioned problems, the total area of the emitter of the bipolar transistor is optimized as shown in FIG. 4. Also, the bipolar transistor formation regions II are arranged considering the degree of freedom for arrangement as shown in FIG. 4, which is quite different from the arrangement of the bipolar transistor formation regions II as shown in FIG. 3.

In each of the photodiode formation regions I is formed a region III where an N sink having no photoelectric function is formed. The N sink formation region III occupies a portion of a light-receiving surface of the photodiode, which will be described later. As a result, photoelectric conversion efficiency, which is defined as the ratio of optical power per unit light-receiving area to outputted current, is decreased. Nevertheless, an electric field at the part where carriers are created by the photons can be optimized, parasitic resistance formed in series is reduced, whereby the response speed is improved.

Referring to FIGS. 5 and 6, the aforesaid N sink formation regions III are not formed in the photodiode formation regions I.

Since the N sink formation regions III are not provided, regions for contributing to the photoelectric conversion are not reduced.

However, an electric field in the horizontal direction is weakened, and thus the electric filed in the horizontal direction becomes zero at the middle part of an anode between P+ polysilicon regions with the result that drift speed of the carriers is decreased and the frequency characteristics are deteriorated. It should be noted, however, that the semiconductor device may be realized on the basis of a circuit design having no N sink formation regions formed in the photodiode formation regions.

The photodiode, which is the light-receiving element constituting the semiconductor device according to the present invention, may be made in the shape of a semiconductor chip by using a process for manufacturing a bipolar transistor. The semiconductor device may be used for a blue wavelength of 405 nm or CD/DVD red wavelengths of 650/780 nm. Of course, the semiconductor device may be used for not only the blue wavelength of 405 nm but also CD/DVD red wavelengths of 650/780 nm.

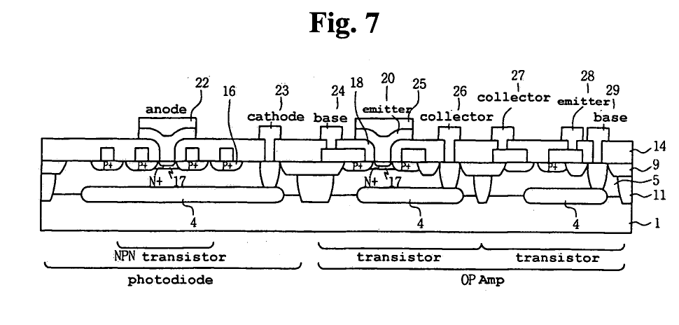

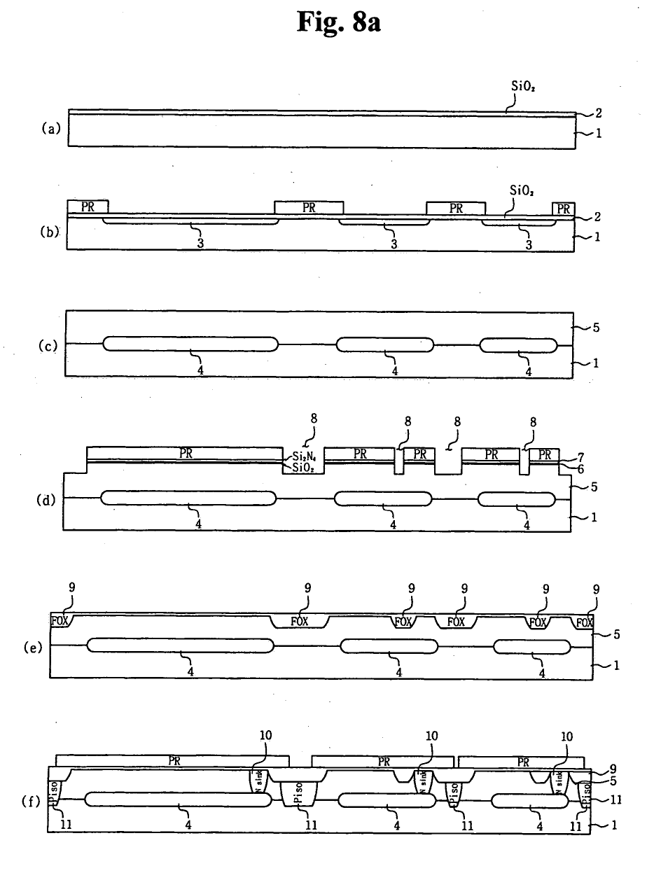

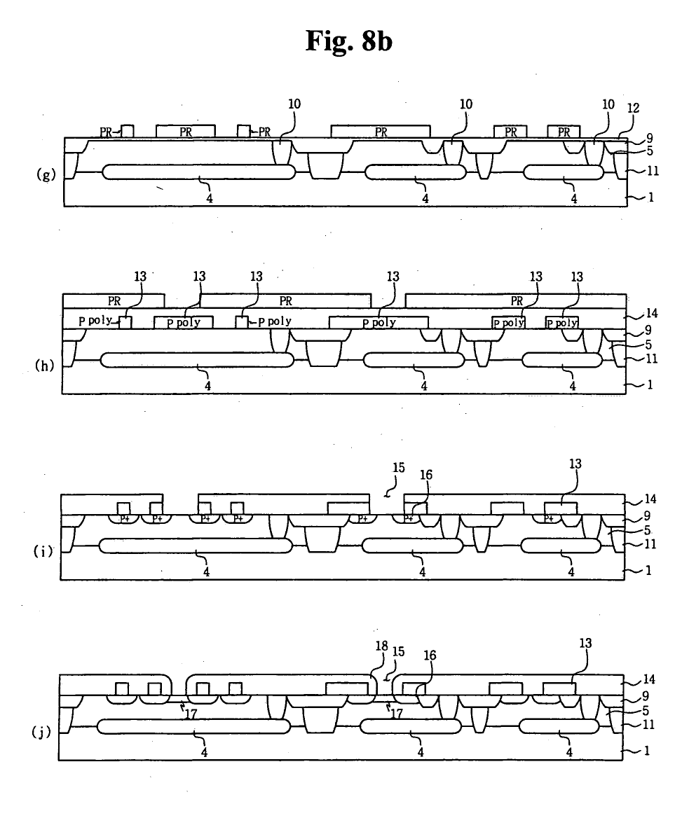

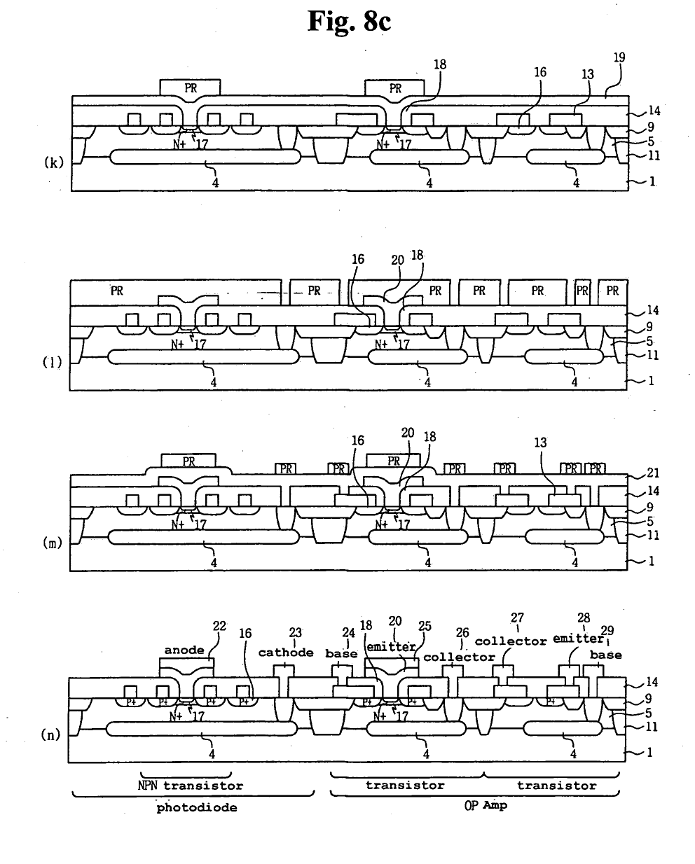

Now, a semiconductor device having light-receiving elements and amplifying elements incorporated in the same chip according to a first preferred embodiment of the present invention and a method of manufacturing the same will be described in detail with reference to FIGS. 7 and 8.

FIG. 7 is a sectional view taken along line A-A′ of FIG. 3, showing a semiconductor device having light-receiving elements and amplifying elements incorporated in the same chip according to a first preferred embodiment of the present invention, and FIGS. 8a to 8c are sectional views showing successive steps of a process for manufacturing a semiconductor device having light-receiving elements and amplifying elements incorporated in the same chip according to a first preferred embodiment of the present invention.

As shown in FIG. 8a (a), a semiconductor substrate 1 having a P type epitaxial silicon layer having a predetermined thickness formed thereon is oxidized in oxygen atmosphere satisfying prescribed conditions to form a silicon oxide (SiO₂) insulation layer 2 having a predetermined thickness on the P type epitaxial silicon layer.

After the silicon oxide insulation layer 2 is formed on the P type epitaxial silicon layer of the semiconductor substrate 1 as described above, N+ buried layers 4 are formed as shown in FIG. 8a (b) and (c).

More specifically, the silicon oxide insulation layer 2 is wholly coated with photoresist PR, and then a masking process is performed on the remaining parts excluding regions 3 where the N+ buried layers 4 are to be formed (hereinafter referred to as “N+ buried layer formation regions 3”).

Subsequently, the N+ buried layer formation regions 3 are exposed and developed to form the N+ buried layer formation regions 3.

The photoresist PR that is not masked and thus exposed is removed during the development, and the masked photoresist PR is left.

After the N+ buried layer formation regions 3 are formed as described above, a prescribed ion, i.e., an arsenic (As) impurity ion is implanted into the N+ buried layer formation regions 3 with the photoresist removed so that the N+ buried layers 4 as shown in FIG. 8a (c) are finally formed.

Subsequently, the masked photoresist PR which had been used to form the N+ buried layers 4 and the silicon oxide insulation layer 2 are removed, and then an N type epitaxial silicon layer 5 is formed by epitaxially growing the silicon substrate as shown in FIG. 8a (c).

After the N type epitaxial silicon layer 5 is formed, field oxide (FOX) films 9 are formed as shown in FIG. 8a (d) and (e).

More specifically, on a silicon oxide (SiO₂) film 6 formed by oxidizing the N type epitaxial silicon layer 5 is deposited Si₃N₄ to form a Si₃N₄ deposit layer 7, and then the silicon oxide film 6 and the Si₃N₄ deposit layer 7 are coated with photoresist PR to form regions 8 where the field oxide films 9 are to be formed (hereinafter referred to as “field oxide film formation regions 8”) on the silicon oxide film 6 and the Si₃N₄ deposit layer 7.

Subsequently, a masking process is performed on the remaining parts excluding the field oxide film formation regions 8, and then they are exposed and developed.

When the photoresist PR on the field oxide film formation regions 8 which are not masked and thus exposed is removed by etching, a portion of the N type epitaxial silicon layer 5 is etched as well as the Si₃N₄ deposit layer 7 and the silicon oxide film 6.

After the field oxide film formation regions 8 are formed through the above-mentioned process, the masked photoresist is removed, and a thermal oxidizing process is carried out on the surfaces where the masked photoresist is removed to form the field oxide films 9 as shown in FIG. 8a (e).

After the field oxide films 9, which are relatively thick oxide films having a thickness of 3000 to 5000 Angstroms in which elements are not formed, are formed through the thermal oxidizing process, the Si₃N₄ deposit layer 7 is etched by an etching process, and the silicon oxide film 6 is etched. Then, the surface of the silicon oxide film 6 is oxidized again.

In should be noted that the regions where the Si₃N₄ deposit layer 7 is selectively formed are not oxidized so that the Si₃N₄ deposit layer 7 excludes the external oxygen.

After the field oxide films 9 are formed as described above, a prescribed impurity is implanted to form N sink regions 10 as shown in FIG. 8a (f).

More specifically, the field oxide films 9 are wholly coated with photoresist PR. Subsequently, a masking process is performed on the remaining parts excluding regions where the N sink regions 10 are to be formed, and then they are exposed and developed.

The photoresist PR that is not masked and thus exposed is removed during the development, and the masked photoresist PR is left.

A prescribed ion, i.e., a phosphorus (P) impurity ion is implanted through the parts where the photoresist PR is removed by a high-energy ion implantation process. The implanted phosphorus impurity is diffused to form a diffusion layer that reaches the N+ buried layers 4 through the N type epitaxial silicon layer 5. As a result, the N sink regions 10 are formed.

When the N sink regions 10 are formed as described above, the electric resistance is reduced, whereby the S/N ratio is improved. Also, the electric field of the depletion layer, in which the carriers used as output current are excited by light, is uniformly improved to obtain the good frequency characteristics, although regions for contributing to the photoelectric conversion are reduced.

It should be noted, however, that the semiconductor device of the present invention may be realized without the N sink regions 10.

After the N sink regions 10 are formed as described above, P isolation layers 11 are formed as shown in FIG. 8a (f).

More specifically, the photoresist which had been used to form the N sink regions 10 is removed, and then the substrate is wholly coated with photoresist PR to form the P isolation layers 11.

After the coating process is carried out as described above, a masking process is performed on the remaining parts excluding regions where the P isolation layers 11 are to be formed, and then they are exposed and developed.

The photoresist PR which is not masked and thus exposed is removed during the development, and the masked photoresist PR is left.

Subsequently, a prescribed ion, i.e., a boron (B) impurity ion is implanted through the parts where the photoresist PR is removed by a high-energy ion implantation process. The implanted boron impurity is diffused to form a diffusion layer which extends from the field oxide films 9 to a predetermined depth of the semiconductor substrate 1 through the N type epitaxial silicon layer 5. As a result, the P isolation layers 11 are formed.

After the P isolation layers 11 are formed as described above, a P type polysilicon layer 12 is formed as shown in FIG. 8b (g).

More specifically, the residual photoresist which had been used to form the P isolation layers 11 is removed, and then the SiO2 is etched by an etching process.

Subsequently, a polysilicon depositing process is carried out to form the P type polysilicon layer 12 as shown in FIG. 8b (g), and then boron (B) is ion implanted into the entire P type polysilicon layer 12.

The ion implanted depth of the boron is set in such a manner that the boron does not penetrate through the P type polysilicon layer 12. Consequently, most of the boron ion implanted in the P type polysilicon layer 12 resides within the P type polysilicon layer 12.

After the P type polysilicon layer 12 is formed as described above, predetermined P type polysilicon patterns 13 are formed as shown in FIG. 8b (h).

More specifically, a photoresist coating process is carried out again on the P type polysilicon layer 12 having the boron ion implanted therein to form the P type polysilicon patterns 13 on the P type polysilicon layer 12.

Thereafter, a masking process is performed on the remaining parts excluding regions where the P type polysilicon patterns 13 are to be formed, and then they are exposed and developed.

The photoresist PR which is not masked and thus exposed is removed during the development, and the masked photoresist PR is left.

Subsequently, the P type polysilicon layer 12 excluding the part where the photoresist PR is left is etched, and then the residual photoresist is removed, so that the P type polysilicon patterns 13 are formed on the P type polysilicon layer 12. On the etched P type polysilicon layer 12 is deposited an interlayer dielectric (ILD) 14.

After the interlayer dielectric (ILD) 14 is deposited as described above, an opening 15, in which an emitter is formed later, is formed as shown in FIG. 8b (i).

More specifically, the interlayer dielectric 14 is coated with photoresist PR, and then the photoresist PR is exposed and developed using a mask for forming the opening 15, in which the emitter is formed later.

At this time, the photoresist PR which is not masked and thus exposed is removed during the development so that the opening 15 is formed, and the masked photoresist PR is left.

After the opening 15, in which the emitter is formed later, is formed, the interlayer dielectric 14 deposited on the unmasked regions is etched by an etching process. The P type polysilicon patterns 13 formed on the P type polysilicon layer 12 is also etched by the aforesaid etching process.

Subsequently, the masked photoresist is removed, and then a drive-in process is carried out to form P+ polysilicon regions 16 from the P type polysilicon patterns 13.

More specifically, the P type polysilicon patterns 13 formed on the P type polysilicon layer 12 by the ion implantation of boron contain a large amount of boron, and atoms of the boron contained in the P type polysilicon patterns 13 diffuse into the N type epitaxial silicon layer 5 by means of the drive-in process.

Parts containing silicon which make contact with the P type polysilicon patterns 13 formed on the P type polysilicon layer 12 due to the diffusion described above are converted into high-concentration P+ polysilicon regions 16. As a result, the P+ polysilicon regions 16 are formed around the P type polysilicon patterns 13.

The drive-in process is a kind of heat treatment, which is carried out in an oxygen-free atmosphere, i.e., in almost 100 percent nitrogen atmosphere. Consequently, the surface of the silicon is not oxidized by the drive-in process.

After the P+ polysilicon regions 16 are formed around the P type polysilicon patterns 13 as described above, boron is ion implanted between the P+ polysilicon regions 16 to form a P type base 17.

To insulate the P type polysilicon patterns 13 formed on the P type polysilicon layer 12 from the N type epitaxial silicon layer 5, another interlayer dielectric may be just a little more stacked on the interlayer dielectric 14, and then a slight etching process may be carried out to form a side wall 18.

The side walls 18 maintain insulation between the P type polysilicon patterns 13 formed on the P type polysilicon layer 12 and the N type epitaxial silicon layer 5. Consequently, the side walls 18 also serve to accurately maintain an optimum distance between the N type epitaxial silicon layer 5 and the P+ polysilicon regions 16.

It should be also noted that the side walls 18 may be formed by an etch-back process after another interlay dielectric connecting the opening parts between the interlayer dielectric 14 is further deposited.

After the boron is ion implanted between the P+ polysilicon regions 16 to form the P type base 17 as described above, N type polysilicon is deposited to form an N type polysilicon layer 19 as shown in FIG. 8c (k).

The formation of the N type polysilicon layer 19 will be hereinafter described in detail with reference to FIG. 8c (k). The N type polysilicon layer 19 is formed by twice depositing polysilicon.

P type polysilicon is formed when an acceptor, such as boron, is implanted into polysilicon. On the other hand, N type polysilicon is formed when a donor, such as phosphorus (P) or arsenic (As), is ion implanted into the polysilicon. The N type polysilicon layer 19 is formed with the N type polysilicon.

Polysilicon is deposited on the upper surface of the semiconductor substrate and grown as shown in FIG. 8c (k). Thereafter, arsenic is ion implanted into the polysilicon to form the N type polysilicon layer 19, and then a drive-in process is carried out to form an emitter layer.

According to the drive-in process, the impurity in the N type polysilicon layer 19 is diffused into the P type base 17 to form a N+ well region.

After the N type polysilicon layer 19 is formed as described above, an emitter pattern 20, from which the emitter is formed later, is formed as shown in FIG. 8c (l).

More specifically, the N type polysilicon layer 19 is coated with photoresist PR to form the emitter layer on the N type polysilicon layer 19.

Thereafter, a masking process is performed on the remaining parts excluding a region where the emitter layer is formed, and then they are exposed and developed.

The photoresist PR which is not masked and thus exposed is removed during the development, and the masked photoresist PR is left.

Subsequently, the N type polysilicon layer 19 excluding the part where the photoresist PR is left is etched, and then the residual photoresist is removed, so that the emitter pattern 20 is formed on the N type polysilicon layer 19.

After the emitter pattern 20 is formed on the N type polysilicon layer 19 as described above, the N type polysilicon layer 19 is coated again with photoresist PR, which is exposed and developed using a mask, so that metal contacts are formed.

At this time, the interlayer dielectric 14 in the unmasked region is etched by an etching process, and the masked photoresist is removed. Subsequently, a metal is deposited on the upper surface of the semiconductor substrate to form a metal layer 21 as shown in FIG. 8c (m).

After the metal layer is formed as described above, metal contacts 22 to 29 having prescribed shapes for forming electrical connections to the outside are formed as shown in FIG. 8c (n).

More specifically, the metal layer 21 formed by depositing the metal is coated with photoresist PR, and then the metal layer 21 is exposed and developed using a mask for forming the metal contacts.

At this time, the metal layer 21 at the regions where the photoresist is unmasked and thus exposed is etched by an etching process.

As shown in FIG. 8c (m), the photoresist on the emitter pattern 20 of the N type polysilicon layer 19 is slightly sunken inward as compared to the emitter pattern 20 of the N type polysilicon layer 19, and then the metal is etched on the basis of the shapes of the aforesaid photoresist. Consequently, the emitter pattern 20 of the N type polysilicon layer 19 is protruded from the metal layer at the time when an etching process on the metal is completed.

After that, the extruded emitter pattern 20 of the N type polysilicon layer 19 is etched so that the extruded emitter pattern 20 of the N type polysilicon layer 19 is removed, and then the residual photoresist PR is removed. In this manner, the manufacture of the semiconductor device is completed.

The semiconductor device having light-receiving elements and amplifying elements incorporated in the same chip according to the present invention, which is manufactured as described above, has a NPN transistor including an anode 22 of the photodiode and a cathode 23 of the photodiode on the left side of a semiconductor substrate. On the right side of the semiconductor substrate are formed a NPN transistor including a base electrode 24, an emitter electrode 25 and a collector electrode 26, and a PNP transistor including a collector electrode 27, an emitter electrode 28 and a base electrode 29, which serve as an amplifying unit for amplifying current outputted from the photodiode, which is very weak due to photoelectric conversion.

In the semiconductor device of the present invention with the above-stated construction, the photodiode and the operational amplifier (OP-AMP) adopting a high-speed bipolar transistor process are incorporated in the same semiconductor chip on the basis of a high-speed bipolar process as a wafer process. As a result, the bipolar transistor formed on the right side of the semiconductor chip has the same structure as the bipolar transistor for the OP-AMP formed on a region apart from another region where the photodiode is formed on the same semiconductor chip, as shown in FIG. 8c (n). Consequently, an additional manufacturing process is required.

Furthermore, the semiconductor device of the present invention has the structure in which bipolar transistors for amplification are arranged in a lattice pattern in such a manner that they surround photodiodes in photodiode formation regions, which means that transistors for amplifying weak current outputted from the photodiodes are formed in the photodiode regions. In addition, bipolar transistors for performing ultrashort amplification of the output signal from the photodiodes may also be arranged in a lattice pattern in such a manner that they surround photodiodes in photodiode regions.

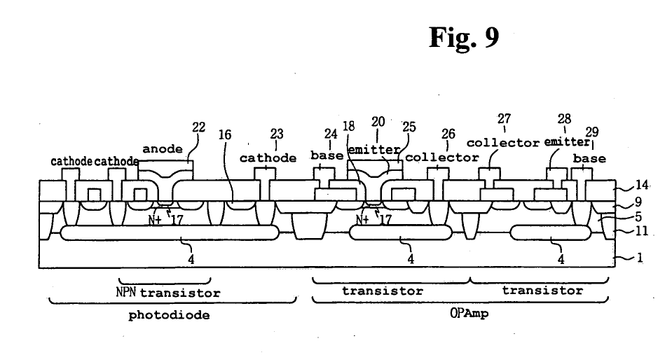

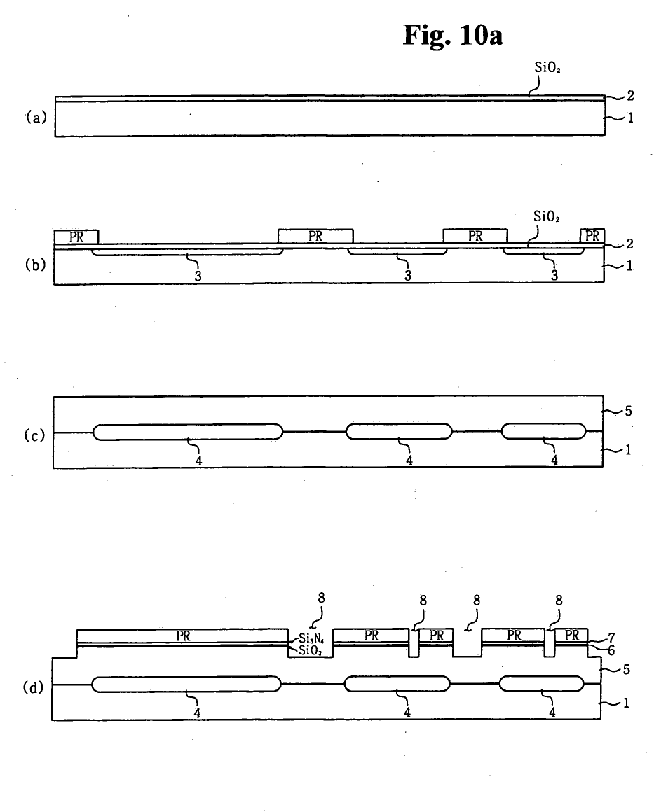

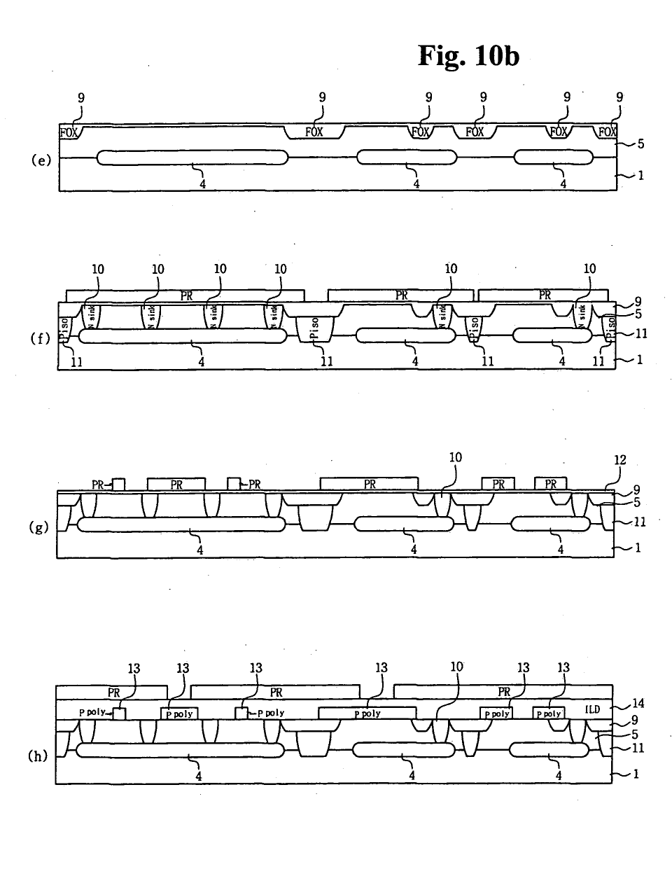

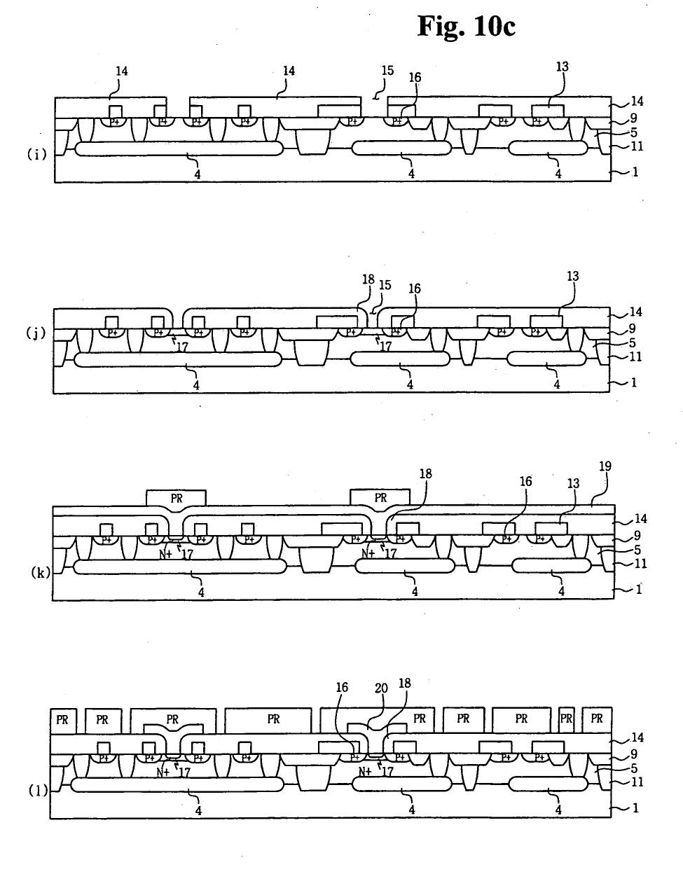

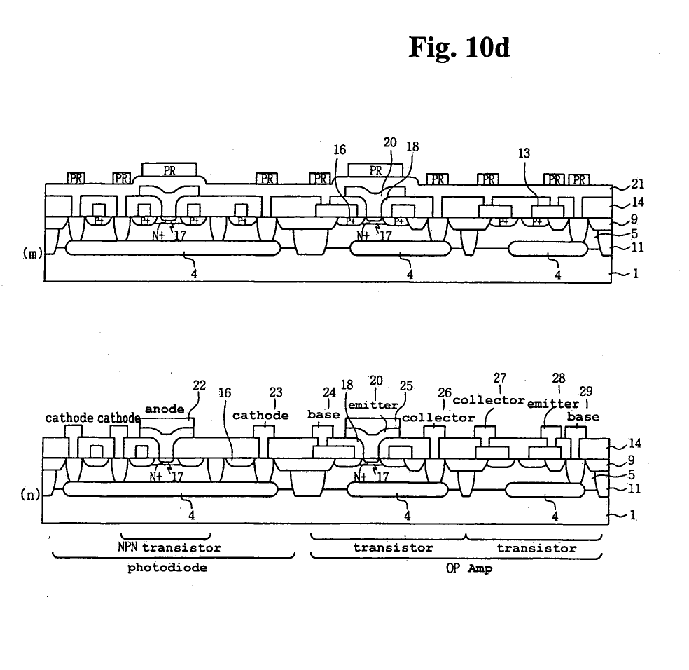

Now, a semiconductor device having light-receiving elements and amplifying elements incorporated in the same chip according to a second preferred embodiment of the present invention and a method of manufacturing the same will be described in detail with reference to FIGS. 9 and 10.

FIG. 9 is a sectional view showing a semiconductor device having light-receiving elements, which are suitable for a CD having an applicable wavelength of 650 nm or a DVD having an applicable wavelength of 780 nm, and amplifying elements incorporated in the same chip according to a second preferred embodiment of the present invention, and FIGS. 10a to 10d are sectional views showing successive steps of a process for manufacturing a semiconductor device having light-receiving elements and amplifying elements incorporated in the same chip according to a second preferred embodiment of the present invention.

The semiconductor device having light-receiving elements and amplifying elements incorporated in the same chip according to the second preferred embodiment of the present invention and the method of manufacturing the same are different from the semiconductor device having light-receiving elements and amplifying elements incorporated in the same chip according to the first preferred embodiment of the present invention and the method of manufacturing the same in that all of the N sink regions are formed between the P+ polysilicon layers in the light-receiving elements.

Accordingly, the semiconductor device according to the second preferred embodiment of the present invention and the method of manufacturing the same are identical to the semiconductor device according to the first preferred embodiment of the present invention and the method of manufacturing the same, except that all of the N sink regions are formed between the P+ polysilicon layers in the light-receiving elements in the case of the second preferred embodiment. Therefore, the same reference numerals denote the same parts and detailed descriptions thereof are omitted.

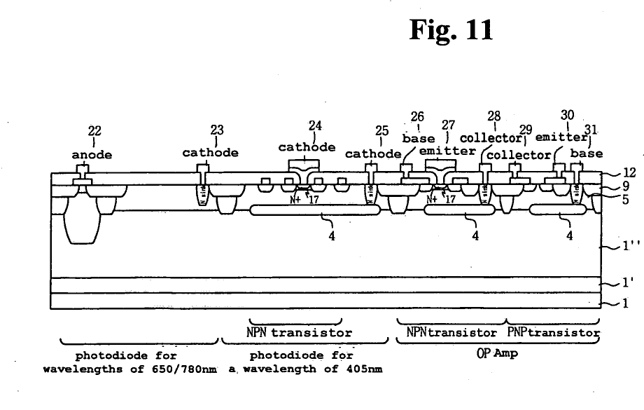

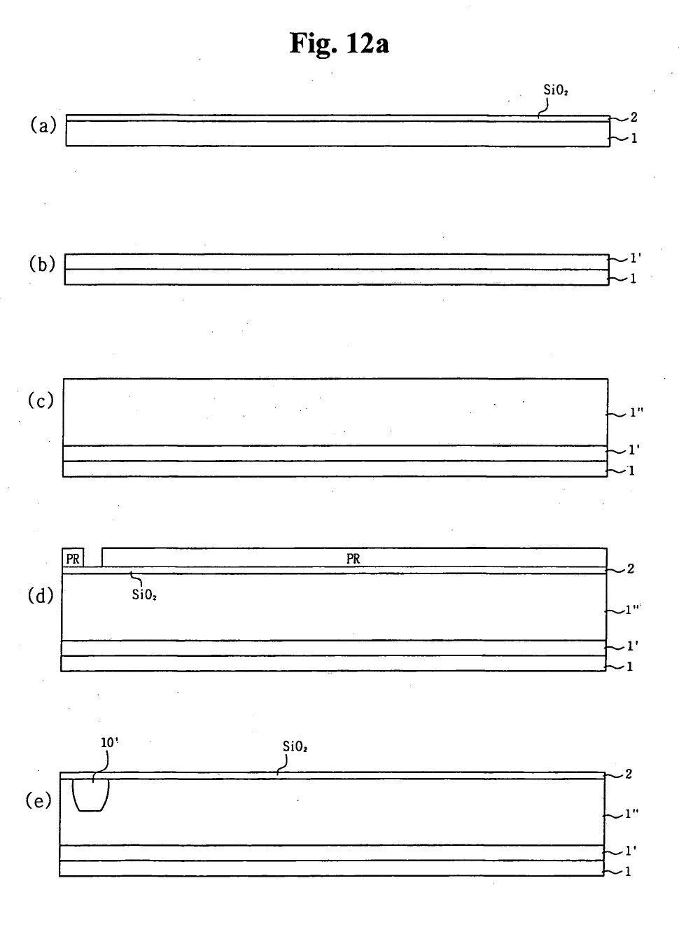

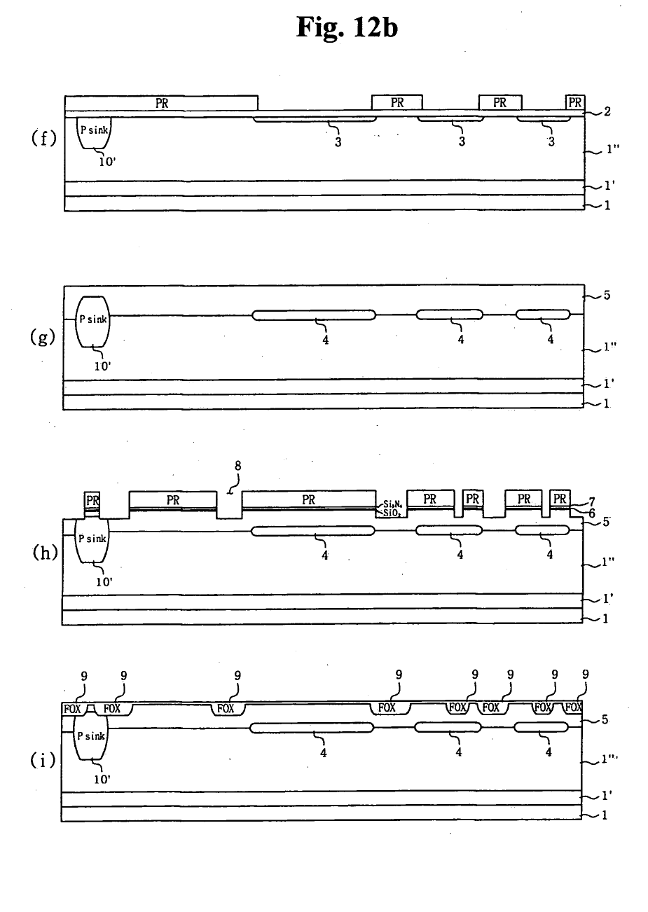

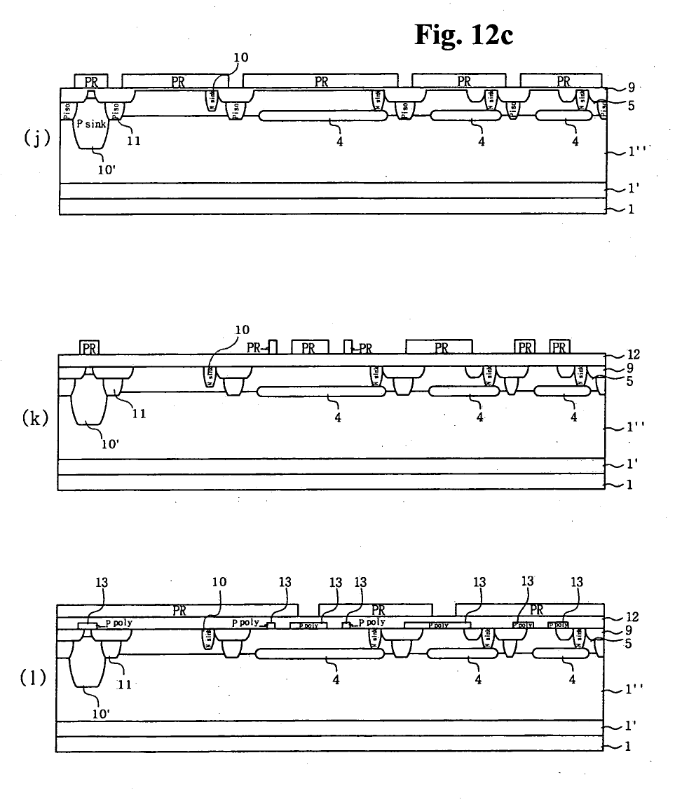

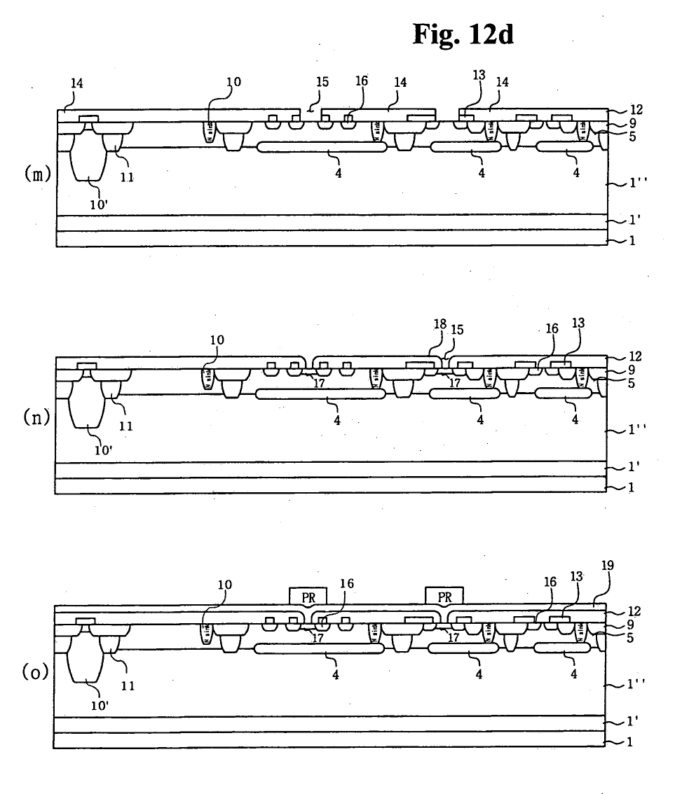

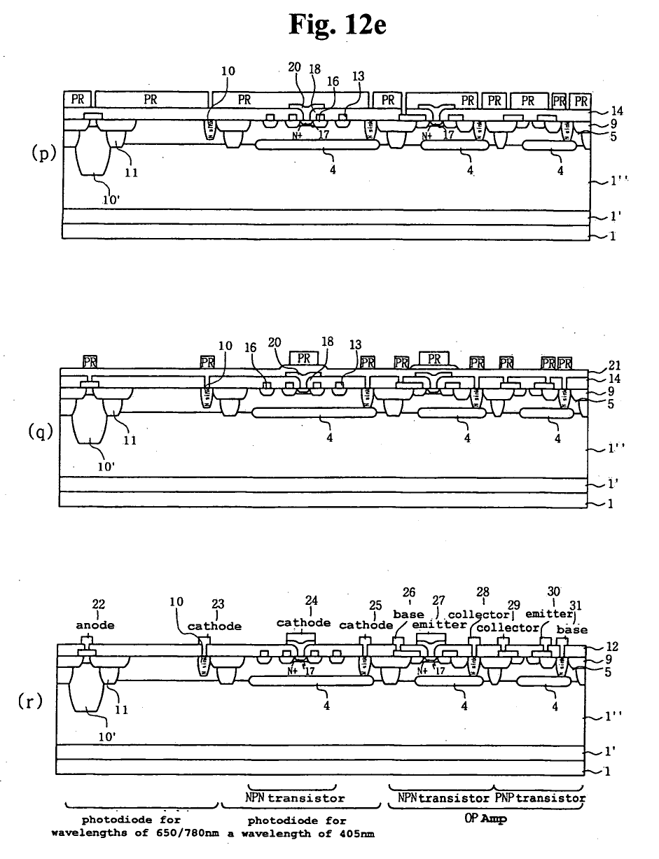

Now, a semiconductor device having light-receiving elements and amplifying elements incorporated in the same chip according to a third preferred embodiment of the present invention and a method of manufacturing the same will be described in detail with reference to FIGS. 11 and 12.

FIG. 11 is a sectional view showing a semiconductor device having light-receiving elements, which are used for not only a blue wavelength but also CD/DVD red wavelengths of 650/780 nm, and amplifying elements incorporated in the same chip according to a third preferred embodiment of the present invention, and FIGS. 12a to 12f are sectional views fully showing successive steps of a process for manufacturing a semiconductor device having light-receiving elements and amplifying elements incorporated in the same chip according to a third preferred embodiment of the present invention.

As shown in FIG. 12a (a), a semiconductor substrate 1 having a P type epitaxial silicon layer having a predetermined thickness formed thereon is oxidized in oxygen atmosphere satisfying prescribed conditions to form a silicon oxide (SiO₂) insulation layer 2 having a predetermined thickness on the P type epitaxial silicon layer.

Subsequently, a prescribed ion, i.e., a boron (B) impurity ion is implanted into the N+ buried layer formation regions 3 through the silicon oxide insulation layer 2, and then a drive-in process is carried out to epitaxially grow a P+ buried layer 1′, as shown in FIG. 12a (b).

After the P+ buried layer 1′ is formed as described above, the silicon oxide insulation layer 2 is etched so that the silicon oxide insulation layer. 2 is removed, and then the P+ buried layer 1′ diffuses to form a P type epitaxial layer 1″, as shown in FIG. 12a (c).

After the P type epitaxial layer 1″ is formed as described above, a P sink region 10′ is formed as shown in FIG. 12a (d) and (e).

More specifically, another silicon oxide insulation layer 2 having a prescribed thickness is formed on the P type epitaxial layer 1″, and then the silicon oxide insulation layer 2 is wholly coated with photoresist PR.

Subsequently, a masking process is performed on the remaining parts excluding a part where the P sink region 10′ is formed (hereinafter referred to as “P sink region formation part”), and then the P sink region formation part is exposed and developed so that the P sink region formation part is formed.

The photoresist PR that is not masked and thus exposed is removed during the development, and the masked photoresist PR is left.

After the P sink region formation part is formed as described above, a prescribed impurity ion, i.e., a boron (B) impurity ion is implanted into the P sink region formation part so that the P sink region 10′ is finally formed.

After the P sink region 10′ is formed as described above, N+ buried layers 4 are formed as shown in FIG. 12a (f) and (g).

More specifically, the silicon oxide insulation layer 2 having a prescribed thickness is formed on the P type epitaxial layer, and then the silicon oxide insulation layer 2 is wholly coated with photoresist PR.

Subsequently, a masking process is performed on the remaining parts excluding regions 3 where the N+ buried layers 4 are to be formed (hereinafter referred to as “N+ buried layer formation regions”), and then the N+ buried layer formation regions are exposed and developed so that the N+ buried layer formation regions 3 are formed.

After the N+ buried layer formation regions 3 are formed as described above, a prescribed ion, i.e., an arsenic (As) impurity ion is implanted into the N+ buried layer formation regions 3 with the photoresist removed so that the N+ buried layers 4 are finally formed.

Subsequently, the masked photoresist PR which had been used to form the N+ buried layers 4 and the silicon oxide insulation layer 2 are removed, and then an N type epitaxial silicon layer 5 is formed by epitaxially growing the silicon substrate.

After the N type epitaxial silicon layer 5 is formed as described above, field oxide (FOX) films 9 are formed as shown in FIG. 12b (h) and (i).

More specifically, on a silicon oxide (SiO₂) film 6 formed by oxidizing the N type epitaxial silicon layer 5 is deposited Si₃N₄ to form a Si₃N₄ deposit layer 7, and then the silicon oxide film 6 and the Si₃N₄ deposit layer 7 are coated with photoresist PR to form regions 8 where the field oxide films 9 are to be formed (hereinafter referred to as “field oxide film formation regions 8”) on the silicon oxide film 6 and the Si₃N₄ deposit layer 7.

Subsequently, a masking process is performed on the remaining parts excluding the field oxide film formation regions 8, and then they are exposed and developed.

When the photoresist PR on the field oxide film formation regions 8 which are not masked and thus exposed is removed by etching, a portion of the N type epitaxial silicon layer 5 is etched as well as the Si₃N₄ deposit layer 7 and the silicon oxide film 6.

After the field oxide film formation regions 8 are formed through the above-mentioned process, the masked photoresist is removed, and a thermal oxidizing process is carried out on the surfaces where the masked photoresist is removed to form the field oxide films 9 as shown in FIG. 12b (i).

After the field oxide films 9, which are relatively thick oxide films having a thickness of 3000 to 5000 Angstroms in which elements are not formed, are formed through the thermal oxidizing process, the Si₃N₄ deposit layer 7 is etched by an etching process, and the silicon oxide film 6 is etched. Then, the surface of the silicon oxide film 6 is oxidized again.

In should be noted that the regions where the Si₃N₄ deposit layer 7 is selectively formed are not oxidized so that the Si₃N₄ deposit layer 7 excludes the external oxygen.

After the field oxide films 9 are formed as described above, a prescribed impurity is implanted to form an N sink region 10 and P isolation layers 11 as shown in FIG. 12c (j) and (k).

More specifically, the field oxide films 9 are wholly coated with photoresist PR. Subsequently, a masking process is performed on the remaining parts excluding regions where the N sink region 10 is formed, and then they are exposed and developed.

The photoresist PR that is not masked and thus exposed is removed during the development, and the masked photoresist PR is left.

A prescribed ion, i.e., a phosphorus (P) impurity ion is implanted through the parts where the photoresist PR is removed by a high-energy ion implantation process. The implanted phosphorus impurity is diffused to form a diffusion layer that reaches the N+ buried layers 4 through the N type epitaxial silicon layer 5. As a result, the N sink region 10′ is formed.

When the N sink region 10 is formed as described above, the electric resistance is reduced, whereby the S/N ratio is improved. Also, the electric field of the depletion layer, in which the carriers used as output current are excited by light, is uniformly improved to obtain the good frequency characteristics, although regions for contributing to the photoelectric conversion are reduced.

It should be noted, however, that the semiconductor device of the present invention may be realized without the N sink region 10.

Subsequently, the photoresist which had been used to form the N sink region 10 is removed, and then the substrate is wholly coated with photoresist PR to form the P isolation layers 11.

After the coating process is carried out as described above, a masking process is performed on the remaining parts excluding regions where the P isolation layers 11 are to be formed, and then they are exposed and developed.

The photoresist PR which is not masked and thus exposed is removed during the development, and the masked photoresist PR is left.

Subsequently, a prescribed ion, i.e., a boron (B) impurity ion is implanted through the parts where the photoresist PR is removed by a high-energy ion implantation process. The implanted boron impurity is diffused to form a diffusion layer which extends from the field oxide films 9 to a predetermined depth of the semiconductor substrate 1 through the N type epitaxial silicon layer 5. As a result, the P isolation layers 11 are formed.

After the P isolation layers 11 are formed as described above, a P type polysilicon layer 12 is formed as shown in FIG. 12c (k).

More specifically, the residual photoresist which had been used to form the P isolation layers 11 is removed, and then the SiO2 is etched by an etching process, as shown in FIG. 12c (k).

Subsequently, a polysilicon depositing process is carried out to form the P type polysilicon layer 12 as shown in FIG. 12c (k), and then boron (B) is ion implanted into the entire P type polysilicon layer 12.

The ion implanted depth of the boron is set in such a manner that the boron does not penetrate through the P type polysilicon layer 12. Consequently, most of the boron ion implanted in the P type polysilicon layer 12 resides within the P type polysilicon layer 12.

After the P type polysilicon layer 12 is formed as described above, predetermined P type polysilicon patterns 13 are formed as shown in FIG. 12c (l).

More specifically, a photoresist coating process is carried out again on the P type polysilicon layer 12 having the boron ion implanted therein to form the P type polysilicon patterns 13 on the P type polysilicon layer 12.

Thereafter, a masking process is performed on the remaining parts excluding regions where the P type polysilicon patterns 13 are to be formed, and then they are exposed and developed.

The photoresist PR which is not masked and thus exposed is removed during the development, and the masked photoresist PR is left.

Subsequently, the P type polysilicon layer 12 excluding the part where the photoresist PR is left is etched, and then the residual photoresist is removed, so that the P type polysilicon patterns 13 are formed on the P type polysilicon layer 12. On the etched P type polysilicon layer 12 is deposited an interlayer dielectric (ILD) 14.

After the interlayer dielectric (ILD) 14 is deposited as described above, an opening 15, in which an emitter is formed later, is formed as shown in FIG. 12d (m).

More specifically, the interlayer dielectric 14 is coated with photoresist PR, and then the photoresist PR is exposed and developed using a mask for forming the opening 15, in which the emitter is formed later.

At this time, the photoresist PR which is not masked and thus exposed is removed during the development so that the opening 15 is formed, and the masked photoresist PR is left.

After the opening 15, in which the emitter is formed later, is formed as described above, the interlayer dielectric 14 deposited on the unmasked regions is etched by an etching process. The P type polysilicon patterns 13 formed on the P type polysilicon layer 12 is also etched by the aforesaid etching process.

Subsequently, the masked photoresist is removed, and then a drive-in process is carried out to form P+ polysilicon regions 16 from the P type polysilicon patterns 13.

More specifically, the P type polysilicon patterns 13 formed on the P type polysilicon layer 12 by the ion implantation of boron contain a large amount of boron, and atoms of the boron contained in the P type polysilicon patterns 13 diffuse into the N type epitaxial silicon layer 5 by means of the drive-in process.

Parts containing silicon which make contact with the P type polysilicon patterns 13 formed on the P type polysilicon layer 12 due to the diffusion described above are converted into high-concentration P+ polysilicon regions 16. As a result, the P+ polysilicon regions 16 are formed around the P type polysilicon patterns 13.

The drive-in process is a kind of heat treatment, which is carried out in an oxygen-free atmosphere, i.e., in almost 100 percent nitrogen atmosphere. Consequently, the surface of the silicon is not oxidized by the drive-in process.

After the P+ polysilicon regions 16 are formed around the P type polysilicon patterns 13 as described above, boron is ion implanted between the P+ polysilicon regions 16 to form a P type base 17 as shown in FIG. 12d (n).

To insulate the P type polysilicon patterns 13 formed on the P type polysilicon layer 12 from the N type epitaxial silicon layer 5, another interlay dielectric connecting the opening parts between the interlayer dielectric 14 may be further deposited, and then the side walls 18 may be formed by an etch-back process.

The side walls 18 maintain insulation between the P type polysilicon patterns 13 formed on the P type polysilicon layer 12 and the N type epitaxial silicon layer 5. Consequently, the side walls 18 also serve to accurately maintain an optimum distance between the N type epitaxial silicon layer 5 and the P+ polysilicon regions 16.

After the boron is ion implanted between the P+ polysilicon regions 16 to form the P type base 17 as described above, N type polysilicon is deposited to form an N type polysilicon layer 19 as shown in FIG. 12d (o).

The formation of the N type polysilicon layer 19 will be hereinafter described in detail with reference to FIG. 12d (o). The N type polysilicon layer 19 is formed by twice depositing polysilicon.

P type polysilicon is formed when an acceptor, such as boron, is implanted into polysilicon. On the other hand, N type polysilicon is formed when a donor, such as phosphorus (P) or arsenic (As), is ion implanted into the polysilicon. The N type polysilicon layer 19 is formed with the N type polysilicon.

Polysilicon is deposited on the upper surface of the semiconductor substrate and grown as shown in FIG. 12c (o). Thereafter, arsenic is ion implanted into the polysilicon to form the N type polysilicon layer 19, and then a drive-in process is carried out to form an emitter layer.

After the N type polysilicon layer 19 is formed as described above, an emitter pattern 20, from which the emitter is formed later, is formed as shown in FIG. 12e (p).

More specifically, the N type polysilicon layer 19 is coated with photoresist PR to form the emitter layer on the N type polysilicon layer 19.

Thereafter, a masking process is performed on the remaining parts excluding a region where the emitter layer is formed, and then they are exposed and developed.

The photoresist PR which is not masked and thus exposed is removed during the development, and the masked photoresist PR is left.

Subsequently, the N type polysilicon layer 19 excluding the part where the photoresist PR is left is etched, and then the residual photoresist is removed, so that the emitter pattern 20 is formed on the N type polysilicon layer 19.

After the emitter pattern 20 is formed on the N type polysilicon layer 19 as described above, the N type polysilicon layer 19 is coated again with photoresist PR, which is exposed and developed using a mask, so that metal contacts are formed.

At this time, the interlayer dielectric 14 in the unmasked region is etched by an etching process, and the masked photoresist is removed. Subsequently, a metal is deposited on the upper surface of the semiconductor substrate to form a metal layer 21 as shown in FIG. 12e (q).

After the metal layer is formed as described above, metal contacts 22 to 29 having prescribed shapes for forming electrical connections to the outside are formed as shown in FIG. 12e (r).

More specifically, the metal layer 21 formed by depositing the metal is coated with photoresist PR, and then the metal layer 21 is exposed and developed using a mask for forming the metal contacts.

At this time, the metal layer 20 at the regions where the photoresist is unmasked and thus exposed is etched by an etching process.

As shown in FIG. 12e (q), the photoresist PR on the emitter pattern 20 of the N type polysilicon layer 19 is slightly sunken inward as compared to the emitter pattern 20 of the N type polysilicon layer 19, and then the metal is etched on the basis of the shapes of the aforesaid photoresist. Consequently, the emitter pattern 20 of the N type polysilicon layer 19 is protruded from the metal layer at the time when an etching process on the metal is completed.

After that, the extruded emitter pattern 20 of the N type polysilicon layer 19 is etched so that the extruded emitter pattern 20 of the N type polysilicon layer 19 is removed, and then the residual photoresist PR is removed. In this manner, the manufacture of the semiconductor device is completed.

As apparent from the above description, the present invention provides a semiconductor device comprising light-receiving elements for receiving light reflected from an optical disc to convert the received light into electric signals, and amplifying elements for amplifying the electric signals outputted from the light-receiving elements wherein the light-receiving elements and the amplifying elements are incorporated in the same chip so that the signals are amplified before noise due to wiring is generated, thereby improving the S/N ratio and suitably corresponding to high-speed playback of the optical disc.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductor device comprising:
a plurality of light-receiving elements for receiving optical signals having predetermined wavelengths reflected from an optical recording medium to convert the received optical signals into electric signals, the light-receiving elements being arranged in a lattice pattern; and
amplifying elements for amplifying the electric signals outputted from the light-receiving elements to externally transmit the amplified electric signals, the amplifying elements being spaced apart from each other by a predetermined distance in a lattice pattern while being interposed between the light-receiving elements.

2. The device as set forth in claim 1, wherein each of the light-receiving elements has an N sink region formed therein, the N sink region being provided for optimizing an electric field at the region where carriers are created.

3. The device as set forth in claim 1, wherein the light-receiving elements are photodiodes operating at a blue wavelength of 405 nm.

4. The device as set forth in claim 1, wherein the light-receiving elements are photodiodes operating at CD/DVD red wavelengths of 650/780 nm.

5. The device as set forth in claim 1, wherein the light-receiving elements are composed of a monolithic combination of photodiodes operating at a blue wavelength of 405 nm and photodiodes operating at CD/DVD red wavelengths of 650/780 nm.

6. The device as set forth in claim 1, wherein the amplifying elements are bipolar transistors.

7. The device as set forth in claim 1, wherein the semiconductor device comprises:
a semiconductor substrate;
N+ buried layers formed by implanting an impurity into regions formed through a masking process on predetermined parts of the semiconductor substrate;
an N type epitaxial layer formed by epitaxially growing the silicon substrate, the N type epitaxial layer being arranged on the upper surface of the semiconductor substrate, the N+ buried layers being disposed between the N type epitaxial layer and the semiconductor substrate;
field oxide films formed by oxidizing the N type epitaxial layer, depositing a Si₃N₄ deposit layer, etching regions formed through a masking process on predetermined parts, and carrying out a thermal oxidizing process;
P isolation layers formed by coating again the field oxide films with photoresist, implanting a prescribed impurity into regions formed through a masking process on the coated parts, and diffusing the impurity from the field oxide films to the semiconductor substrate;
a P type polysilicon layer formed by depositing polysilicon on the N type epitaxial layer to form predetermined P type polysilicon patterns;
an interlayer dielectric deposited on the upper surface of the P type polysilicon layer after the P type polysilicon patterns are formed;
P+ polysilicon regions formed by diffusing the impurity from the P type polysilicon patterns to the N type epitaxial layer;
a P type base formed by implanting a prescribed impurity ion between the P+ polysilicon regions;
an N type polysilicon layer deposited on the upper surface of the masked interlayer dielectric for forming an emitter pattern having a predetermined shape; and
a metal layer deposited on the regions not coated by the interlayer dielectric for forming metal contacts performing electrical connection to the outside, whereby the semiconductor device is operated at a prescribed blue wavelength.

8. The device as set forth in claim 7, wherein the semiconductor device further comprises N sink regions formed by coating field oxide films with photoresist, implanting a prescribed impurity into regions formed through a masking process on the photoresist, and diffusing the impurity to the N+ buried layers through the N type epitaxial layer.

9. The device as set forth in claim 8, wherein all of the N sink regions are formed between the P+ polysilicon layers constituting the light-receiving elements, and wherein the semiconductor device is operated at a prescribed red wavelength.

10. The device as set forth in claim 7, wherein the semiconductor device further comprises side walls, formed by additionally depositing another interlayer dielectric connecting the opening parts between the interlayer dielectric and carrying out an etch-back process, for insulating the P type polysilicon patterns formed on the P type polysilicon layer from the N type epitaxial silicon layer.

11. The device as set forth in claim 7, wherein boron impurity is ion implanted into the entire P type polysilicon layer, and wherein the ion implanted depth of the boron is set such that the boron does not penetrate through the P type polysilicon layer, whereby the boron ion implanted in the P type polysilicon layer resides within the P type polysilicon layer.

12. The device as set forth in claim 1, wherein four amplifying elements are arranged close to one light-receiving element.

13. The device as set forth in claim 1, wherein two amplifying elements are arranged close to one light-receiving element.

14. The device as set forth in claim 1, wherein the semiconductor device comprises:
a P type semiconductor substrate;
a P+ buried layer formed by implanting a prescribed impurity ion into the P type semiconductor substrate and carrying out a drive-in process;
a P type epitaxial layer formed by diffusing the impurity implanted in the P+ buried layer;
a P sink region formed by coating the P type epitaxial layer with photoresist, implanting a prescribed impurity into a region formed through a masking process on the, photoresist, and diffusing the impurity into the P type epitaxial layer by a prescribed depth;
N+ buried layers formed by implanting an impurity into regions formed through a masking process on predetermined parts of the semiconductor substrate;
an N type epitaxial layer formed by epitaxially growing the silicon substrate, the N type epitaxial layer being arranged on the upper surface of the semiconductor substrate, the N+ buried layers being disposed between the N type epitaxial layer and the semiconductor substrate;
field oxide films formed by oxidizing the N type epitaxial layer, depositing a Si₃N₄ deposit layer, etching regions formed through a masking process on predetermined parts, and carrying out a thermal oxidizing process;
P isolation layers formed by coating again the field oxide films with photoresist, implanting a prescribed impurity into regions formed through a masking process on the coated parts, and diffusing the impurity from the field oxide films to the semiconductor substrate;
a P type polysilicon layer formed by depositing polysilicon on the N type epitaxial layer to form predetermined P type polysilicon patterns;
an interlayer dielectric deposited on the upper surface of the P type polysilicon layer after the P type polysilicon patterns are formed;
P+ polysilicon regions formed by diffusing the impurity from the P type polysilicon patterns to the N type epitaxial layer;
a P type base formed by implanting a prescribed impurity ion between the P+ polysilicon regions;
an N type polysilicon layer deposited on the upper surface of the masked interlayer dielectric for forming an emitter pattern having a predetermined shape; and
a metal layer deposited on the regions not coated by the interlayer dielectric for forming metal contacts performing electrical connection to the outside,
whereby the semiconductor device is operated not only at a prescribed blue wavelength but also at prescribed CD/DVD red wavelengths.

15. The device as set forth in claim 14, wherein the semiconductor device further comprises N sink regions formed by coating field oxide films with photoresist, implanting a prescribed impurity into regions formed through a masking process on the photoresist, and diffusing the impurity to the N+ buried layers through the N type epitaxial layer.

16. A method of manufacturing a semiconductor device, comprising the steps of:
forming a silicon oxide insulation layer on a semiconductor substrate;
forming N+ buried layers on predetermined etched parts of the semiconductor substrate having the silicon oxide insulation layer formed thereon;
epitaxially growing the semiconductor substrate to form an N type epitaxial layer on the upper surface of the semiconductor substrate;
etching predetermined regions of N type epitaxial layer and then carrying out a thermal oxidizing process to form field oxide films;
implanting a prescribed impurity so that the impurity is diffused from the field oxide films to the semiconductor substrate to form P isolation layers;
depositing polysilicon on the field oxide films to form a P type polysilicon layer;
etching predetermined regions of the P type polysilicon layer to form predetermined P type polysilicon patterns, and depositing interlayer dielectric on the etched regions of the P type polysilicon layer to form an interlayer dielectric layer;
masking a predetermined region of the interlayer dielectric to form an opening provided for forming an emitter terminal therein, and then carrying out a drive-in process so that the impurity is diffused from the P type polysilicon patterns to N type epitaxial layer to form P+ polysilicon regions from the P type polysilicon patterns;
implanting a prescribed impurity ion between the P+ polysilicon regions to form a P type base;
depositing polysilicon on the upper surface of the masked interlayer dielectric to form an N type polysilicon layer so that an emitter pattern having a predetermined shape is formed; and
forming a metal layer on the P type polysilicon patterns not coated by the interlayer dielectric to form metal contacts performing electrical connection to the outside,
wherein the semiconductor device is operated at a prescribed blue wavelength.

17. The method as set forth in claim 16, further comprising implanting a prescribed impurity so that the impurity is diffused from the field oxide films to the N+ buried layers through the N type epitaxial layer to form N sink regions.

18. The method as set forth in claim 17, wherein the step of forming the N sink regions comprises:
coating the field oxide films with photoresist;
masking the remaining parts excluding parts where the N sink regions are to be formed;
exposing and developing the unmasked parts so that the photoresist on the parts where the N sink regions are to be formed is removed to form the parts where the N sink regions are to be formed; and
implanting a prescribed impurity into the parts where the N sink regions are to be formed.

19. The method as set forth in claim 17, wherein the step of forming the N sink regions comprises forming all of the N sink regions between the P+ polysilicon layers in the light-receiving elements, and wherein the semiconductor device is operated at a prescribed red wavelength.

20. The method as set forth in claim 16, wherein the step of forming the interlayer dielectric comprises forming side walls for insulating the P type polysilicon patterns formed on the P type polysilicon layer from the N type epitaxial layer.

21. The method as set forth in claim 16, wherein the step of forming the field oxide films comprises:
oxidizing the N type epitaxial layer to form a silicon oxide film;
depositing Si₃N₄ on the silicon oxide film to form a Si₃N₄ deposit layer;
coating the Si₃N₄ deposit layer with photoresist;
masking the remaining parts excluding field oxide film formation regions;
exposing and developing the unmasked regions so that the photoresist on the field oxide film formation regions is removed to form the field oxide film formation regions; and
etching residual photoresist not removed by the exposing and developing step to etch a portion of the N type epitaxial silicon layer, the silicon oxide film and the Si₃N₄ deposit layer.

22. The method as set forth in claim 16, wherein the step of forming the metal layer comprises etching the emitter pattern of the N type polysilicon layer, the emitter pattern being protruded from the metal layer, to form the metal layer and the emitter pattern with the same size.

23. A method of manufacturing a semiconductor device, comprising the steps of:
forming a silicon oxide insulation layer on a P type semiconductor substrate;
implanting a prescribed impurity ion into the P type semiconductor substrate and carrying out a drive-in process to form a P+ buried layer;
diffusing the impurity implanted in the P+ buried layer to form a P type epitaxial layer;
coating the P type epitaxial layer with photoresist, implanting a prescribed impurity into a region formed through a masking process on the photoresist, and diffusing the impurity into the P type epitaxial layer by a prescribed depth to form a P sink region;
forming N+ buried layers on predetermined etched parts of the semiconductor substrate having the silicon oxide insulation layer formed thereon;
epitaxially growing the semiconductor substrate to form an N type epitaxial layer on the upper surface of the semiconductor substrate;
etching predetermined regions of N type epitaxial layer and then carrying out a thermal oxidizing process to form field oxide films;
implanting a prescribed impurity so that the impurity is diffused from the field oxide films to the semiconductor substrate to form P isolation layers;
depositing polysilicon on the field oxide films to form a P type polysilicon layer;
etching predetermined regions of the P type polysilicon layer to form predetermined P type polysilicon patterns, and depositing interlayer dielectric on the etched regions of the P type polysilicon layer to form an interlayer dielectric layer;
masking a predetermined region of the interlayer dielectric to form an opening provided for forming an emitter terminal therein, and then carrying out a drive-in process so that the impurity is diffused from the P type polysilicon patterns to N type epitaxial layer to form P+ polysilicon regions from the P type polysilicon patterns;
implanting a prescribed impurity ion between the P+ polysilicon regions to form a P type base;
depositing polysilicon on the upper surface of the masked interlayer dielectric to form an N type polysilicon layer so that an emitter pattern having a predetermined shape is formed; and
forming a metal layer on the P type polysilicon patterns not coated by the interlayer dielectric to form metal contacts performing electrical connection to the outside,
wherein the semiconductor device is operated not only at a prescribed blue wavelength but also at prescribed CD/DVD red wavelengths.

24. The method as set forth in claim 23, further comprising implanting a prescribed impurity so that the impurity is diffused from the field oxide films to the N+ buried layers through the N type epitaxial layer to form N sink regions.
